(19) United States
(12) Patent Application Publication
(10) Pub. No.: US 2011/0005920 A1
(43) Pub. Date: Jan. 13, 2011

(54) Low Temperature Deposition of Amorphous Thin Films

(75) Inventors: Ivan Petrov Ivanov, Apple Valley, MN (US); Antoine Khoueir, Apple Valley, MN (US); Wei Tian, Eden Prairie, MN (US); Paul E. Anderson, Eden Prairie, MN (US); Lili Jia, Eden Prairie, MN (US); Yongchul Ahn, Eagan, MN (US); Michael Xuefei Tang, Bloomington, MN (US); Yang Dong, Maple Grove, MN (US)

Correspondence Address: Fellers, Snider, Blankenship, Bailey & Tippens, PC;(Seagate Technology LLC), 100 North Broadway, Suite 1700, Oklahoma City, OK, 73102-8820, US

(73) Assignee: SEAGATE TECHNOLOGY LLC, Scotts Valley, CA (US)

(21) Appl. No.: 12/502,139

(22) Filed: Jul. 13, 2009

(51) Int. Cl. C23C 14/35

(52) U.S. Cl. 204/192.13; 204/298.17; 204/298.08; 204/298.03; 204/192.12

(57) ABSTRACT

Various embodiments of the present invention are generally directed to an apparatus and method for low temperature physical vapor deposition (PVD) of an amorphous thin film layer of material onto a substrate. A PVD chamber is configured to support a substrate and has a cathode target with a layer of sputtering material thereon, an anode shield, and a magnetron assembly adjacent the target. A high impulse power magnetron sputtering (HiPIMS) power supply is coupled to the PVD chamber, the power supply having a charging circuit and a charge storage device. The power supply applies relatively high energy, low duty cycle pulses to the magnetron assembly to sputter, via self ionizing plasma, relatively low energy ions from the layer of sputtering material to deposit an amorphous thin film layer onto the substrate.

### BACKGROUND

Physical vapor deposition (PVD) generally refers to a variety of methods used to deposit thin films of material onto a substrate, such as a surface of a semiconductor wafer. PVD methods utilize a physical material transfer mechanism to deposit the thin film material onto the coated surface, rather than utilizing a chemical reaction at the coated surface as in the case in chemical vapor deposition (CVD).

Various PVD methods include pulsed sputtering, ion beam sputtering, and magnetic assisted sputtering. These and other methods generally form a plasma within a vacuum chamber. The plasma provides accelerated ions that bombard a nearby target. This creates a flux of sputtering material which is ejected from the target and directed onto the substrate wafer. The ejected flux is predominately composed of neutral, metastable atoms of the target material which physically interact, via kinetic effects, with the substrate to form the thin film.

The neutral sputtered atoms will often have an energy distribution peak that is substantially half that of the sublimation energy level of the target material. Some of the sputtered atoms will lose energy in gas-phase collisions before arriving at the substrate. In these conventional methods, there is generally no additional opportunity to accelerate the neutrally sputtered atoms emanating from the target toward the growing film surface on the substrate since the sputtered atoms are in a neutral state.

Bias sputtering, such as via ionized metal plasma and self-ionized plasma, can be used to extract ions from the gas discharge and provide additional ion bombardment during film growth. Negative DC bias voltage or RF bias power can be applied to the wafer to enhance ion bombardment from the ions in the positive column of the low-pressure gas discharge.

While operable, these and other conventional PVD methods often use relatively high duty cycles and/or relatively high density plasmas to ionize the neutral sputtered atoms. This can lead to significant heating of the substrate wafer, which can reach temperatures on the order of around 400-450° Celsius (° C.) or higher.

While elevated temperatures can be readily accommodated by many semiconductor materials, some structures may be adversely affected by higher temperature deposition methods. Exceeding the Curie temperature of a magnetized material may adversely alter the magnetized state of the material.

Conventional PVD processes can also induce significant current densities in the substrate, which may damage resistive sense layers. Some conventional PVD processes further tend to generate columnar microstructures in the deposited material layers, which can result in degraded mechanical and electrical characteristics.

### SUMMARY

Various embodiments of the present invention are generally directed to an apparatus and method for low temperature physical vapor deposition (PVD) of an amorphous thin film conductive layer of material onto a substrate.

In accordance with some embodiments, a physical vapor deposition (PVD) chamber is used to support a substrate. The chamber comprises a cathode target with a layer of sputtering material thereon, an anode shield, and a magnetron assembly adjacent the target. A high impulse power magnetron sputtering (HiPIMS) power supply is coupled to the PVD chamber, the power supply comprising a charging circuit and a charge storage device. The power supply applies pulses to the magnetron assembly to sputter, via self ionizing plasma, relatively low energy ions from the layer of sputtering material to deposit an amorphous thin film conductive layer onto the substrate.

In other embodiments, a physical vapor deposition (PVD) chamber is configured to support a substrate. The chamber comprises a cathode target with a layer of sputtering material thereon, an anode shield, and a magnetron assembly adjacent the target. A high impulse power magnetron sputtering (HiPIMS) power supply is coupled to the PVD chamber, the power supply comprising a charging circuit and a charge storage device. The charge storage device comprises a capacitor and the power supply comprises a switching circuit that facilitates cyclical storage of charge on the capacitor from the charging circuit and discharge of the stored charge from the capacitor to the magnetron assembly. A control circuit and a temperature sensor determine a temperature of the substrate during the deposition of the amorphous thin film layer and provides an indication of the temperature of the substrate to the control circuit. The control circuit further adjusts at least one operational characteristic of the power supply in response to the indication and directs a continued deposition of the amorphous thin film layer using an adjusted operational characteristic. Finally, the power supply applies relatively high energy pulses to the magnetron assembly to sputter, via self ionizing plasma (SIP), relatively low energy ions from the layer of sputtering material to deposit an amorphous conductive thin film layer onto the substrate.

Further in various embodiments, a physical vapor deposition (PVD) chamber that has a cathode target with a layer of sputtering material thereon, an anode shield, and a magnetron assembly adjacent the target is provided. A high impulse power magnetron sputtering (HiPIMS) power supply is then coupled to the PVD chamber, the power supply comprising a charging circuit and a charge storage device. A substrate is supported within the chamber and an amorphous thin film layer is deposited onto the substrate by using the power supply to apply relatively high energy pulses to the magnetron assembly to sputter, via self ionizing plasma (SIP), relatively low energy ions from the layer of sputtering material to the substrate.

These and other features and advantages which characterize the various embodiments of the present invention can be understood in view of the following detailed discussion and accompanying drawings.

### BRIEF DESCRIPTION OF THE DRAWINGS

FIGS. 1A-1C set forth exemplary semiconductor structures that can be formed in accordance with various embodiments of the present invention.

FIG. 2 is a functional block diagram of a physical vapor deposition (PVD) system in accordance with various embodiments.

FIG. 3 is a graphical representation of various operational characteristics of the system of FIG. 2.

FIG. 4A represents a thin film deposited in accordance with the prior art, the prior art film having columnar microstructures.

FIG. 4B is a scanning electron microscope (SEM) image of the prior art thin film of FIG. 4A.

FIG. 5A represents an amorphous thin film deposited by the system of FIG. 2.

FIG. 5B is an SEM image of the thin film of FIG. 5A.

FIG. 6 graphically illustrates respective x-ray diffusion spectrography results of the respective thin films of FIGS. 4-5.

FIG. 7A shows exemplary via fill and coverage characteristics obtained using the system of FIG. 2.

FIG. 7B is a tunneling electron microscope (TEM) image of the structure illustrated in FIG. 7A.

FIG. 8A shows another set of exemplary via fill and coverage characteristics obtained using the system of FIG. 2.

FIG. 8B is a TEM image of the structure of FIG. 8A.

FIGS. 9A-9E show process steps for low temperature via filling.

### DETAILED DESCRIPTION

The present disclosure is generally directed to an apparatus and method for forming an amorphous thin film layer on a substrate using a low temperature physical vapor deposition (PVD) process. In some embodiments, the amorphous thin film is conductive. As explained below, a self ionizing plasma (SIP) PVD chamber utilizes a magnetron driven by a high impulse power magnetron sputtering (HiPIMS) power supply. High energy low duty cycle pulses provide low energy ion bombardment of ions from a layer of sputtering material of a target onto a substrate while maintaining substrate temperatures at extremely low levels, such as less than about 150 degrees Celsius. Current densities at the substrate are also held to a relatively low value, and in some cases are substantially zero. The resulting conductive thin film is provided with uniformly amorphous characteristics.

It has been found that the use of a PVD chamber with an HiPIMS power supply as disclosed herein provides a number of advantageous and unexpected synergistic effects. Unlike conventional PVD processes, columnar structures in the low temperature deposited conductive film are not created. Highly precise layer thicknesses and coverages are achieved, including uniform filling of high aspect ratio vias during directional sputtering.

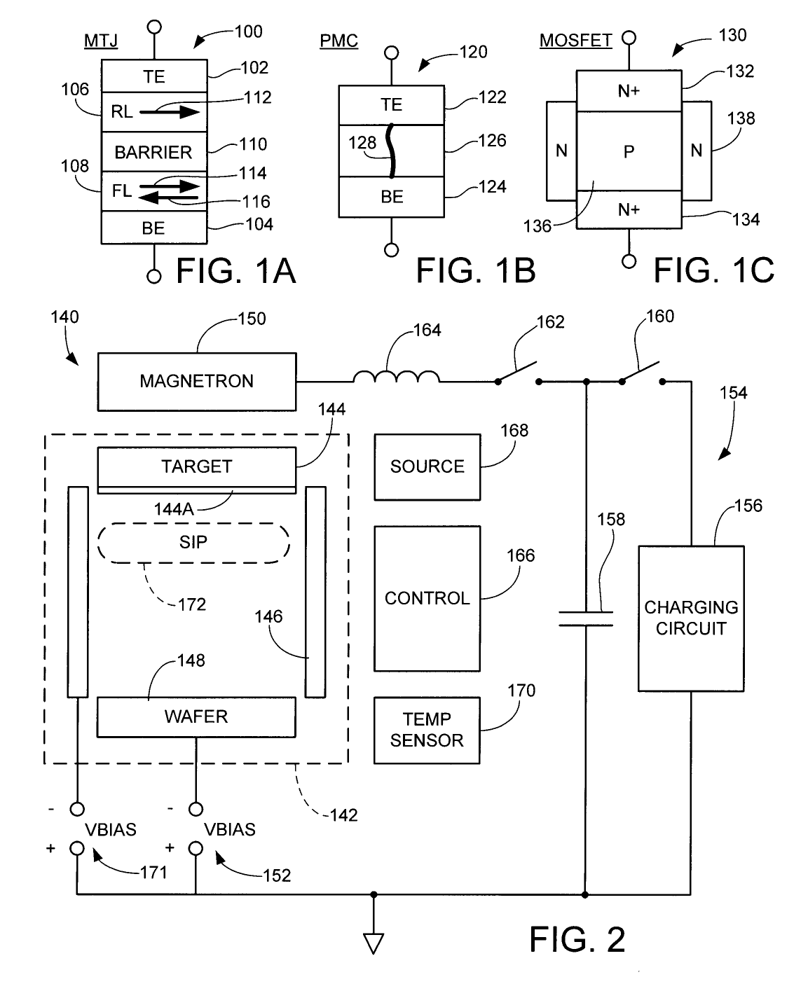

FIGS. 1A-1C set forth a number of semiconductor structures that have features that can be formed in accordance with various embodiments of the present invention. It will be appreciated that the various structures of FIGS. 1A-1C are merely exemplary and are not limiting to the scope of the claimed subject matter.

FIG. 1A shows a magnetic tunneling junction (MTJ) 100 of the type that can be used in a spin-torque transfer random access memory (STRAM) cell. The MTJ 100 includes opposing top and bottom electrodes (TE and BE) 102, 104, a reference layer (RL) 106, a free layer (FL) 108, and a barrier layer 110. The RL has a fixed magnetization in a selected orientation, as indicated by arrow 112. This fixed magnetization can be established in a number of ways such as via pinning to a separate permanent magnet or other layer (not shown).

The FL 108 can take a number of different magnetization orientations as indicated by arrows 114, 116. These different magnetization orientations can be established by the application of suitable programming write currents through the MTJ 100.

The MTJ 100 is characterized as a resistive sense element (RSE) in that the electrical resistance of the MTJ varies in relation to the programmed magnetization orientation of the FL 106. The MTJ 100 takes a relatively low resistance RL when the magnetization orientation of the FL 106 is parallel to that of the RL 104, and a relatively high resistance RH when the magnetization orientation of the FL 106 is opposite (anti-parallel) to that of the RL 104. The programmed state of the MTJ 100 can be sensed by applying a read current through the MTJ and comparing the resulting voltage drop to a reference voltage.

FIG. 1B shows a programmable metallization cell (PMC) 120, such as of the type used in a resistive random access memory (RRAM) cell. Top and bottom electrodes (TE and BE) 122, 124 are separated by an intervening oxide layer 126. The PMC 120 constitutes an RSE in that the PMC normally has a relatively high resistance RH due to the electrical characteristics of the oxide layer 126. Application of a suitable programming write voltage changes the PMC 120 to a low resistance RL state as metal ions pass from the electrodes into the oxide layer to form one or more conductive filament(s) 128. The PMC 120 can be returned to the initial high resistance state by the application of a second programming write voltage with the opposite polarity to drive the metal ions back to the respective electrodes 122, 124.

FIG. 1C illustrates a vertical (3D) metal oxide semiconductor field effect transistor (MOSFET) 130. The transistor 130 can be utilized as a discrete switching device in an electrical circuit. Alternatively, the transistor 130 can be combined with the MTJ 100 of FIG. 1A or the PMC 120 of FIG. 1B to form a stacked 1T1R (“one transistor, one resistive element”) memory cell. In this latter case, the transistor 130 can be utilized as a switching device to control access to the resistive element.

The transistor 130 includes N+ doped source and drain regions 132, 134 separated by a P doped channel region 136. An N doped gate structure 138 surrounds the channel region 136. The NPN configuration of the transistor 130 is normally non-conductive across the drain-source junction, but can be placed in a forward biased conductive state by application of a suitable gate voltage to the gate structure.

Care should be taken during the manufacture of these and other semiconductor structures to ensure that the manufacturing process does not induce apparent or latent defects. For example, the maximum post-MTJ process temperature should not exceed the Curie temperature of the various magnetic layers in the MTJ 100 of FIG. 1A, lest the MTJ be irreversibly damaged.

Similarly, certain oxide films such as the barrier layer 126 in FIG. 1B may be susceptible to undesired changes in underlying chemical makeup or crystalline arrangement as a result of high temperature processing. The passage of large currents through the substrates during a deposition process can also lead to undesired damage to various layers, such as punch-through damage in the layers 126, 136 in FIGS. 1B-1C. In general, low temperature, low current post-processing may be required in a variety of cases to preserve film and/or layer textures, compositions and interfactial microstructure boundaries.

Accordingly, FIG. 2 provides a functional block diagram for a physical vapor deposition (PVD) system 140 useful in forming various layers utilized in a number of semiconductor structures including those of FIGS. 1A-1C. The system is also useful in generating subsequent features, such as conductive traces and interconnecting vias, on a wafer on which the semiconductor structures of FIGS. 1A-1C have already been formed.

The system 140 includes a self ionizing plasma (SIP) physical vacuum deposition (PVD) chamber 142 which houses a target 144, a shield 146 and a substrate 148 (semiconductor wafer). The target 144 comprises a layer of sputtering material 144A, which may form a part of the target material or may be a separate layer of material that is applied to the target. The wafer 148 is supported by an associated pedestal (not separately shown).

A rotating magnetron driver assembly 150 (magnetron) is provided adjacent the target 144. An optional low voltage bias power supply 152 can be used to apply a low power bias to the wafer 148. The magnetron 150 may be water cooled, as desired, to maintain heating of the magnetron below an upper maximum limit.

The magnetron 150 is driven by a high impulse power magnetron sputtering (HiPIMS) power supply 154. The power supply 154 includes a charging circuit 156, a charging capacitor 158, switches 160 and 162, and in-line inductor 164.

A control circuit 166 provides top level control of the system 100 and may be controller based with a GUI interface. A gas source 168 supplies gas to the vacuum chamber 142 as required. A temperature sensor 170 optionally provides temperature measurements and closed loop feedback to the control circuit 166.

During operation, the power supply 154 generally operates to provide high energy, low duty cycle pulses to the magnetron 150. This is carried out by alternately charging the capacitor 158 using the charging circuit 156, and then discharging the stored charge through the inductor 164 to the magnetron 150.

The shield 146 (anode) is biased to a negative potential such as on the order of 500-2000 VDC with respect to the target (cathode) using a shield power supply 171. A suitable vacuum level is applied to the chamber 142, and an inert gas such as Argon Ar or Nitrogen N is injected into the chamber via source 168.

The cathode-anode potential induces a localized zone of plasma adjacent the target. This zone of plasma is represented at 172 and has high local and/or temporal plasma densities such as on the order of about 10¹² cm⁻³. Ions from the plasma 172 bombard the target material 144A, which comprises a suitable metal such as Titanium (Ti) although other metals can be used including but not limited to Tantalum (Ta), Copper (Cu), or Aluminum (Al).

The impact energy of the ions release target metal ions which are directed to and physically deposited on the wafer 148. A self ionizing plasma process is induced whereby some of the target metal ions interact with the plasma 172 and are redirected back to the target, releasing further metal ions for deposition. In some embodiments, Nitrogen (N) is released into the chamber via the source 168 to provide deposition of Titanium Nitride (TiN) or other nitride alloys.

In the system 100, the short discharge times of the capacitor 158 produce relatively high power density levels to the water cooled magnetron, and the sputtered atoms emanating from the target surface are predominantly in single and double charged ionic states. The ions leaving the target surface are accelerated toward the substrate under conditions of low energy ion bombardment to form the thin film under low temperature conditions.

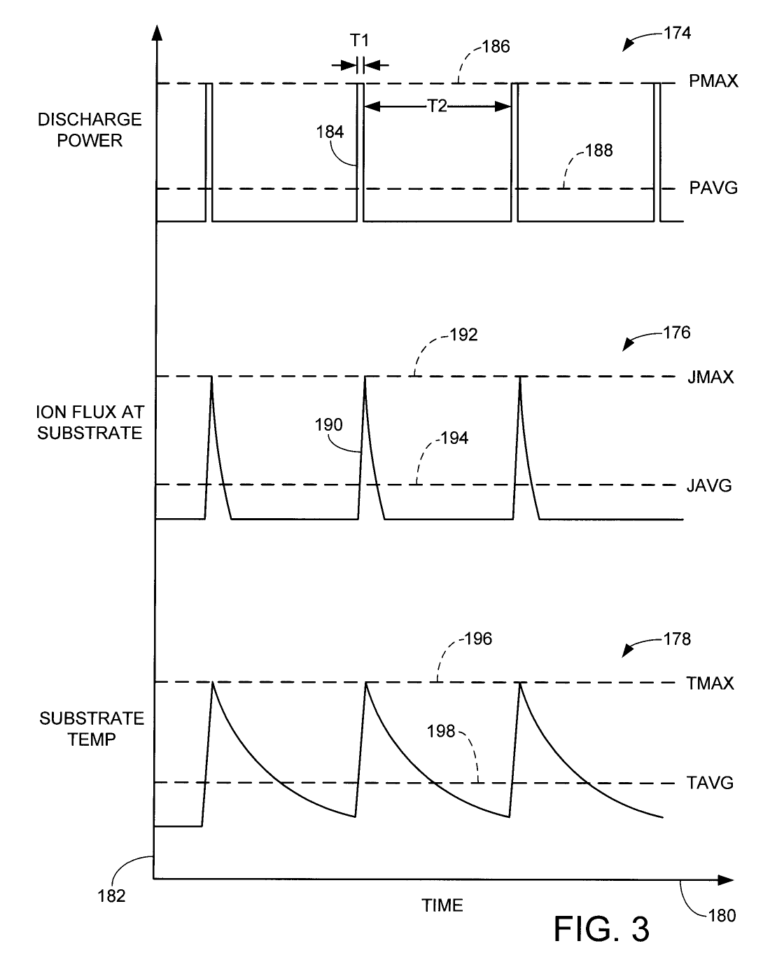

FIG. 3 illustrates exemplary operational characteristics of the system 100. Discharge power, ion flux and substrate temperature curves 174, 176 and 178 are plotted against a common elapsed time x-axis 180 and a common amplitude y-axis 182. The discharge power curve 174 illustrates the use of a relatively low duty cycle, such as on the order of from 0.5% to 5.0%. Duty cycle can be calculated as the ratio T1/(T1+T2), where T1 is the pulse width of each pulse 184 and T2 is the time between adjacent pulses. Low repetition rates are used, such as on the order of around 50-500 pulses per second (50-500 Hz).

The pulses 184 achieve a maximum power level indicated by broken line 186, and a significantly lower average power level as indicated by broken line 188. The respective maximum and average power levels will vary depending on the application. An exemplary maximum power level may be on the order of about 1 MW (10⁶ watts), with average power levels being substantially lower than this range.

The ion flux curve 176 represents the ion flux in terms of current density at the substrate 148. Because of the pulsed nature of the power supply 154, spaced apart occurrences of flux material deposition will take place, as indicated by current pulses 190. These flux pulses will achieve a maximum current density level 192, and a significantly lower average current density level 194. Exemplary maximum current densities may be on the order of about 3-4 A/cm².

The temperature curve 178 represents the cyclical temperature cycling of the substrate 148 during the deposition process. During each cycle, the temperature reaches a maximum temperature level 196 and subsequently falls along an exponential decline path prior to the next pulse. This cycling provides the substrate with an average temperature level 198. In some embodiments, the maximum temperature level will be on the order of about 100-150° C., with average temperatures even lower. In other embodiments, the maximum temperature level will be less than about T=100° C., and may even be at substantially ambient room levels (e.g. around 25-35° C.).

The system 100 generates dense, amorphous thin films with excellent mechanical and electrical properties while maintaining low wafer temperatures. It has been found under some conditions that around 80% to 90% of the sputtered flux emanating the target surface will be single or double charged ions of elements representing the target material chemical composition, e.g., Ti+ and N+ for TiN deposition.

The application of a relatively low anode-cathode negative bias accelerates the ions to the growing film and provides precise control of adatom mobility. In some cases, it has been found unnecessary to supply any bias to the substrate (e.g., power supply 152 in FIG. 2 can be eliminated or switched out of the circuit). The ions emanating from the target surface have an energy distribution with a mean energy of tens of electron volts (eV) extending up to hundreds of eV. Since a single eV has a thermal equivalent of over 11K° C., this advantageously allows the use of low energy ion bombardment on a floating wafer with a net current to the coated substrate close to, or even equal to zero amps. This can be beneficial when ion current to the wafer is not desirable, as in the case of certain RSE configurations where the resistive sensor has already been formed on the wafer.

Unlike prior art methods of plasma generation, the low cycle rate and low duty cycle high-powered sputtering provided by the system 100 allows for heat relaxation of the wafer/pedestal during deposition, as shown in FIG. 3. This limits the buildup of heat within the wafer. Certain types of materials that would normally require high temperature depositions in a PVD process can be deposited at significantly lower temperatures. By way of illustration, dense TiN deposition using a conventional PVD process may require growth temperatures around 400° C. By contrast, the system 100 has been found to be able to efficiently grow amorphous TiN layers at significantly lower temperatures (e.g., T<150° C.).

In some embodiments, temperature measurements are obtained during the sputtering operation by the temperature sensor 170 and provided to the control circuit 166 to set and/or adaptively adjust the various operational parameters of the power supply 154. In this way, closed loop monitoring and control of the wafer temperature can be achieved to ensure some upper maximum limit, such as a Curie temperature, is not exceeded.

Another advantage of the system 100 is the amorphous nature of the resulting thin films. Apart from the higher temperatures required during conventional PVD processing, another limitation with convention PVD processing is the tendency to produce thin conductive films with columnar microstructures.

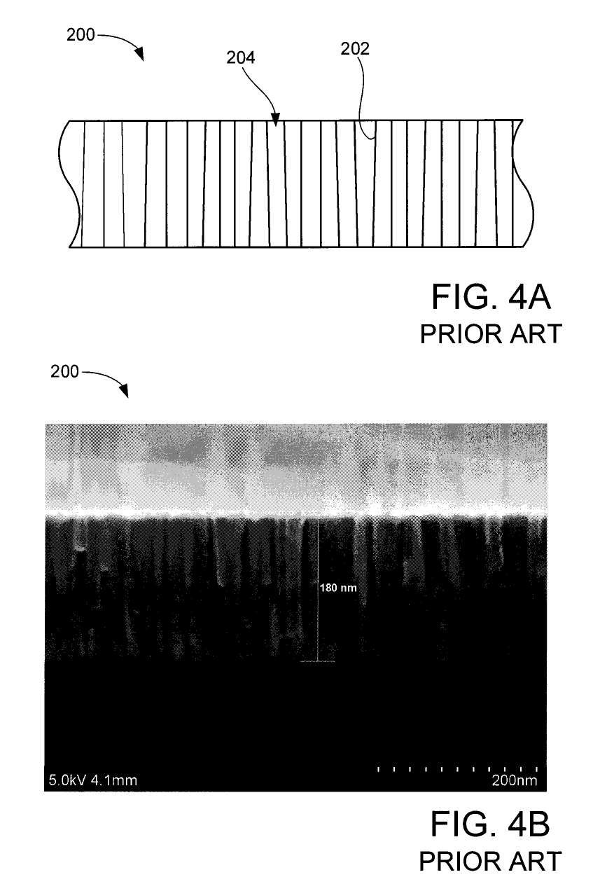

By way of illustration, FIG. 4A represents a layer of TiN 200 deposited using conventional high temperature pulsed PVD processing. The layer 200 includes a number of columns 202 of dense TiN material separated by intervening low grain density columnar boundaries 204. FIG. 4B provides a corresponding scanning electron microscope (SEM) image of the exemplary TiN layer 200 of FIG. 4A. The layer 200 was formed using conventional pulsed PVD processing using high energy ion bombardment and wafer deposition temperatures in the range of about 400-450° C.

The columnar structures in the conventionally deposited TiN layer 200 is not desirable for many embodiments. The columnar structures provide self-shadowing effects which produce low density grain boundaries and which can adversely affect via fill and feature coverage.

Columnar microstructures such as depicted in FIGS. 4A-4B can also provide degradations in mechanical and/or electrical performance, such as reduced mechanical strength and increased electrical resistance and impedance. In the past, designers often utilized some other process such as chemical vapor deposition (CVD) when layers without columnar microstructures were required.

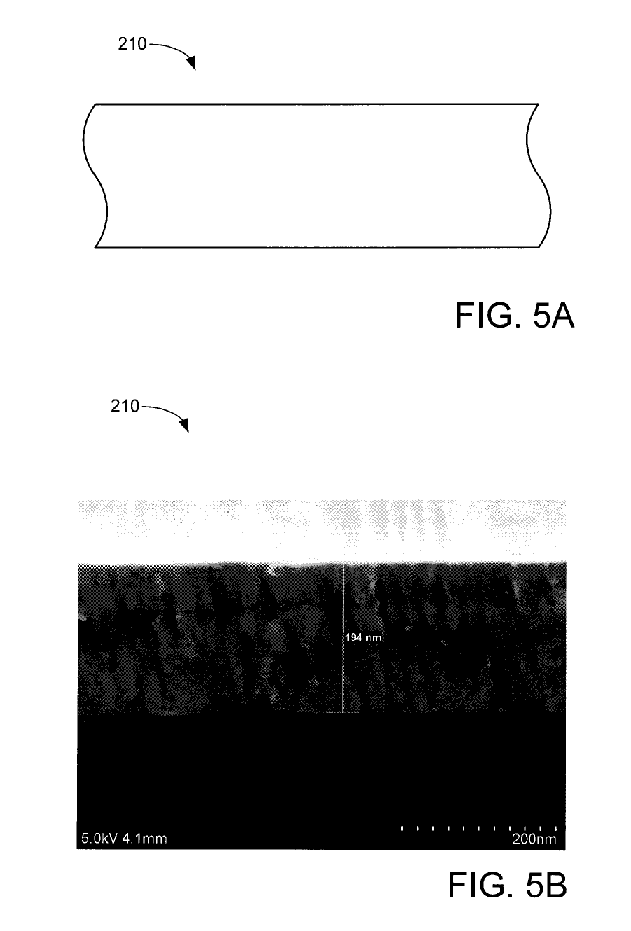

By contrast, FIGS. 5A and 5B provide a corresponding diagram and SEM image of an amorphous layer of TiN 210 formed using the PVD with HiPIMS system 100 of FIG. 2. The layer 210 was deposited with a wafer temperature of T<150° C. Uniformly dense amorphous material is provided substantially without the presence of columnar microstructures. The amorphous nature of the layer 210 provides superior mechanical strength and electrical conductivity characteristics over that provided by the conventional layer 200.

The HiPIMS enhances ionization efficiency of the SIP discharge which significantly increases the plasma density during each high-energy pulse. This leads to high ionization rates of the sputtered atoms to produce the homogenous amorphous TiN film with excellent diffusion properties.

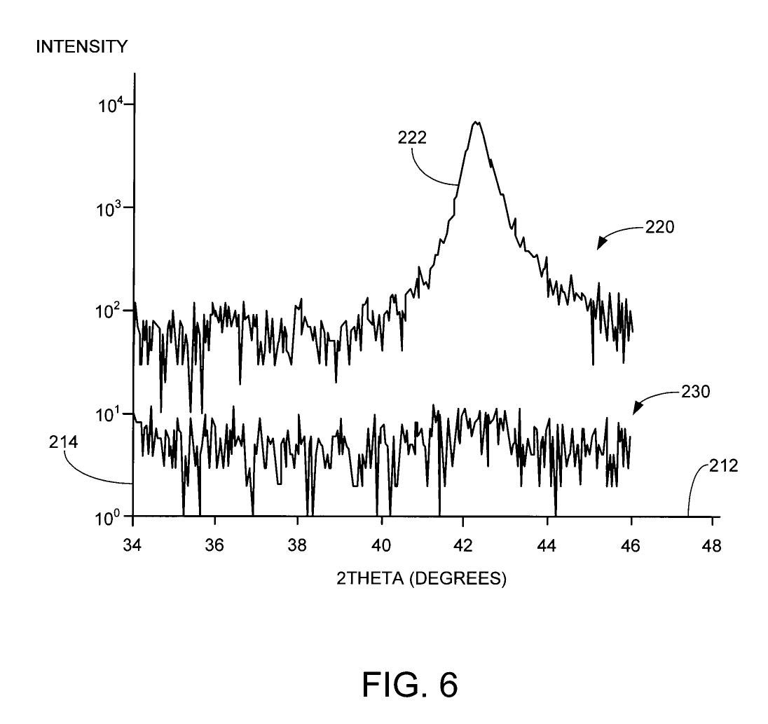

FIG. 6 provides an x-ray diffusion (XRD) spectography analysis of the associated layers 200, 210 in FIGS. 4-5, plotted against a Theta-2Theta (degrees) x-axis 212 and a logarithmic intensity y-axis 214. Curve 220 in FIG. 6 corresponds to the conventional layer 200, and curve 230 corresponds to the layer 210 formed by the system 100. The discontinuous granular nature of the prior art layer 200 is evident by the peak 222 in curve 220, which corresponds to XRD detection of the crystallographic planes of the columnar TiN. By contrast, the amorphous nature of the layer 210 is evident by the substantially constant intensity level of curve 230 over the same range, indicating the lack of significant crystallographic boundaries within the amorphous film.

Another advantage of the low ion-bombardment and low heating mechanism provided by the system 100 of FIG. 2 is the ability to use higher than conventional nitrogen pressures (or nitrogen percentage in an Ar/N₂ mixture) in the chamber 142 during the sputtering process. Testing has confirmed that nitrogen/titanium ratios of greater than 58%/42% can be utilized to form the amorphous films. It is believed that this higher nitrogen content may also contribute to amorphous characteristics of the deposited film.

Another advantage of the processing provided by the system 100 is via fill and coverage. As will be appreciated, vias are often used as a pass-through conductivity path through an insulative boundary layer to connect a lower conductive layer with an upper conductive layer. The system 100 provides effective directional sputtering and complete via fill without key-holing (voids) for a wide variety of via aspect ratios. Via aspect ratio can be calculated as the depth of the via divided by the diameter of the via (depth/diameter).

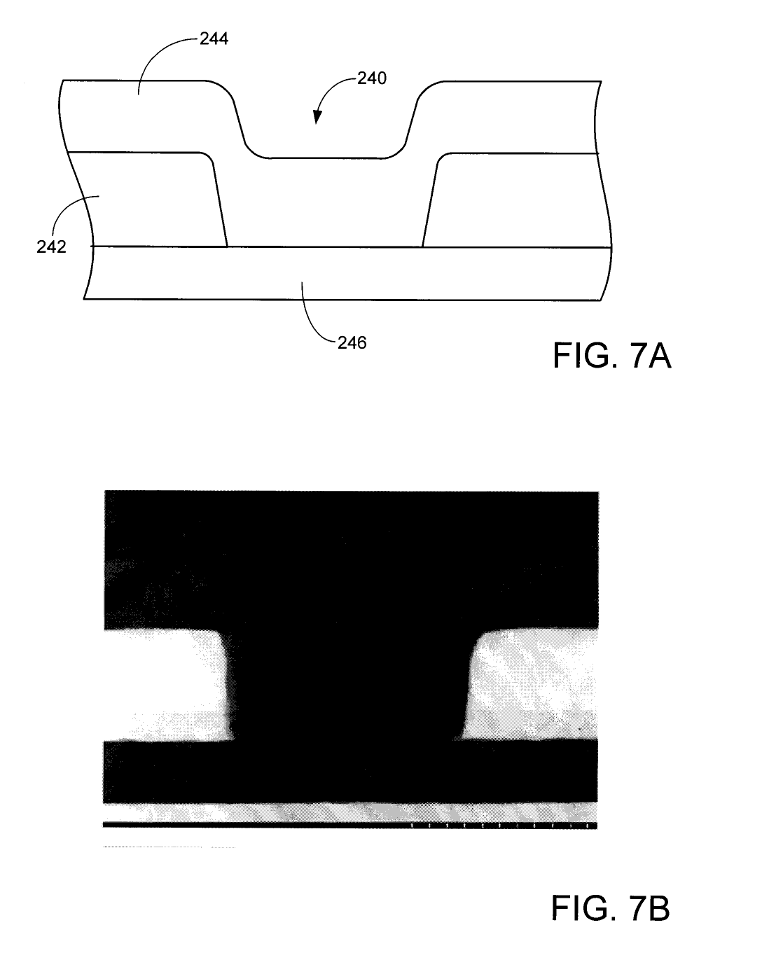

FIG. 7A illustrates a via 240 formed in an insulative layer 242. The via 240 has a relatively lower aspect ratio, on the order of about 0.475. As represented in FIG. 7A, the system 100 deposited a layer 244 of amorphous TiN that provided substantial via fill and surface coverage, resulting in electrical interconnection with an underlying conductive layer 246. Conventional post processing steps such as polishing and etching can be applied to the amorphous Tin layer 244 as desired. A corresponding tunneling electron microscope (TEM) image is set forth in FIG. 7B.

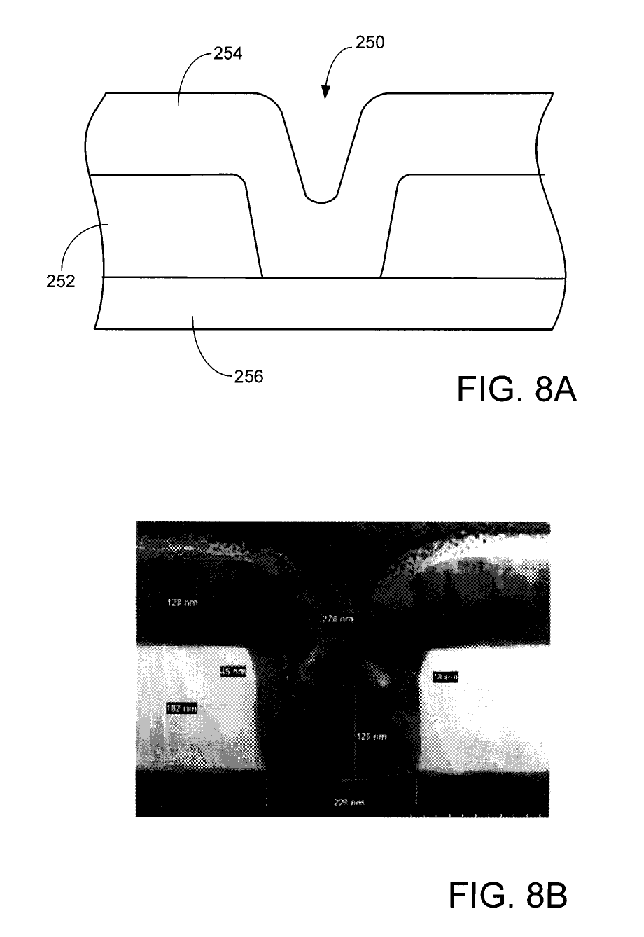

FIG. 8A provides another via 250 formed in an insulative layer 252. The via 250 has a relatively higher aspect ratio, on the order of about 0.75. As before, the PVD processing provided an amorphous TiN layer 256 to fill the via 250 and interconnect with an underlying conductive layer 256. A corresponding TEM image is provided in FIG. 8B.

In some embodiments, the wafer can be subjected to multiple successive steps using the system 100 of FIG. 2 to deposit different types of amorphous thin film conductive layers onto the wafer, including sequencing wherein conductive layers are formed, vias are filled, and conductive features are placed into electrical contact with said filled vias.

It will now be appreciated that the various embodiments presented herein provide a number of advantages over conventional PVD processing. Using an HiPIMS to drive an SIP PVD chamber as disclosed herein provides excellent coverage and filling characteristics at significantly lower temperatures and current densities over conventional processing techniques. The system advantageously provides low-temperature via fill of small vias by a direct fill process, and excellent step coverage for through silicon vias with a variety of different aspect ratios. These are presently areas of great interest to the semiconductor industry, particularly for multi-layer (3D) integrated circuits and memories.

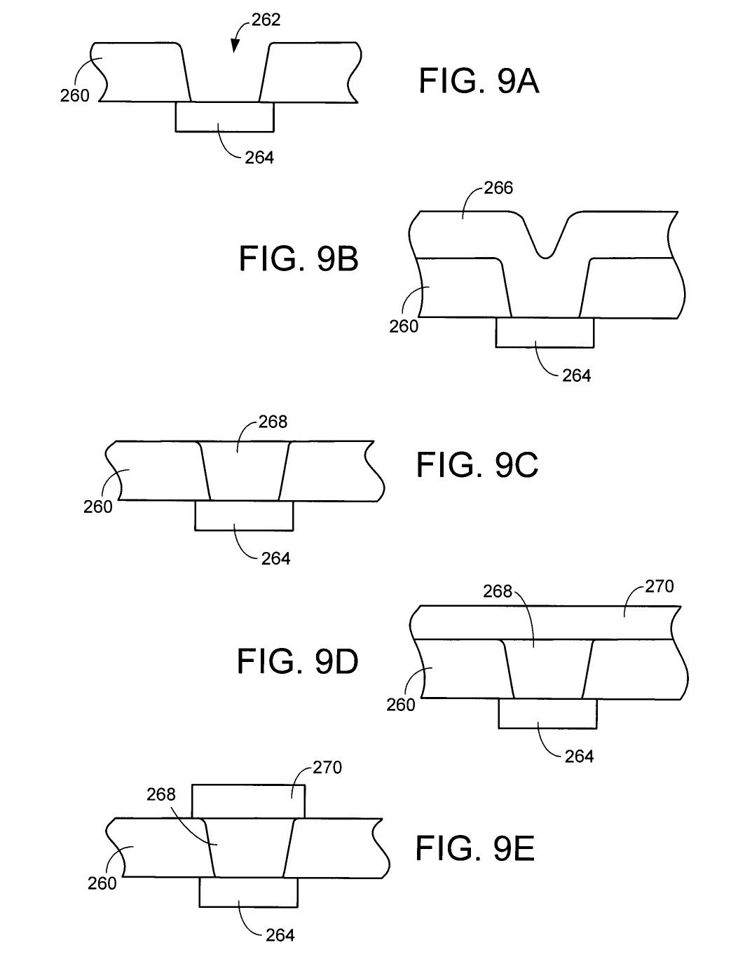

FIGS. 9A-9E display an exemplary direct via filling process whereby complete filling of a via/contact is achieved during the deposition process. As shown in FIG. 9A, a dielectric material 260 includes a via 262 and a first metal 264 positioned adjacent both the via 262 and the dielectric material 260. In an example displayed in FIG. 9B, a via that is 0.2 μm (10⁻⁶ m) in diameter and 0.2 μm high can be subjected to a deposition layer 266 of 0.5 μm of TiN in accordance with the foregoing embodiments, which will completely fill the via and surrounding contact with conducting material.

Subsequently, a polishing operation can polish back 0.3 μm of the TiN, leaving a substantially flat layer of TiN connected to a completely filled via 268 of the TiN material, as shown in FIG. 9C. Such direct filled vias can accommodate small feature sizes and elements particularly in non-volatile memory arrays. In some embodiments, a second metal 270 can be deposited on the filled via 268 so that both the dielectric material 260 and via 268 are enclosed. Furthermore, the second metal 270 can be configured to any number of orientations that enclose the filled via 268 and a portion of the dielectric material 260, such as the configuration displayed in FIG. 9E.

Step coverage is a process whereby vias and contacts are partially filled, allowing the subsequent application of a separate conductive filler material such as Tungsten in a CVD process. Step coverage is used to denote both sidewall and bottom coverage in terms of percentage (%). Bottom coverage is obtained by dividing the thickness of a layer of PVD deposited material at the bottom of the via to the thickness of the material on the flat wafer areas. For example, a 0.1 μm layer of TiN at the bottom of a via and 0.5 μm layer on the flat wafer areas adjacent the via would constitute a 20% bottom coverage. Sidewall coverage is determined in a similar fashion.

Partially filled vias using step coverage in accordance with the various processing disclosed herein can provide a number of benefits in 3D stacking applications where good step coverage is required for relatively large vias (such as on the order of 10 μm in diameter) with high aspect ratios throughout an entire wafer. Conventional PVD processing can often provide a maximum bottom coverage range of from 30-40%. The processing set forth herein, however, has been found to provide bottom coverage of any desired range, including 100% (or even higher) for a wide range of via sizes, aspect ratios and locations on a wafer.

Moreover, as noted above the use of relatively low energy ion bombardment as described herein provides amorphous film characteristics with very little thermal heating of the wafer, which can be particularly useful in applications where higher wafer deposition temperatures and/or currents can induce damage into the semiconductor structure of the wafer. A variety of materials can be sputtered via the PVD processing set forth herein, so the various exemplary materials discussed herein will be understood as being merely illustrative and not limiting. The need for active cooling mechanisms, such as but not limited to the use of a cooling fluid (e.g., recirculating chilled water, etc.) are wholly eliminated to maintain the temperature of the wafer below acceptable levels.

For purposes of the appended claims, consistent with the foregoing discussion it will be understood that reference to amorphous thin film conductive layers and the like will describe deposited materials with substantially no columnar microstructures, as described with reference to FIGS. 4-5.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. An apparatus comprising:
a physical vapor deposition (PVD) chamber configured to support a substrate and comprising a cathode target with a layer of sputtering material thereon, an anode shield, and a magnetron assembly adjacent the target; and
a high impulse power magnetron sputtering (HiPIMS) power supply coupled to the PVD chamber, the power supply comprising a charging circuit and a charge storage device;
wherein the power supply applies relatively high energy pulses to the magnetron assembly to sputter, via self ionizing plasma (SIP), relatively low energy ions from the layer of sputtering material to deposit an amorphous thin film layer onto the substrate.

2. The apparatus of claim 1, wherein the amorphous thin film layer is deposited while the maximum temperature of the substrate is maintained in a range of less than about 150 degrees Celsius.

3. The apparatus of claim 2, wherein the amorphous thin film layer is deposited while a maximum temperature of the substrate is maintained in a range of less than about 100 degrees Celsius without using an active cooling mechanism to cool said substrate.

4. The apparatus of claim 1, wherein the charge storage device comprises a capacitor, and wherein the power supply further comprises a switching circuit that facilitates cyclical storage of charge on the capacitor from the charging circuit and discharge of the stored charge from the capacitor to the magnetron assembly at a duty cycle of from about 0.5% to about 5.0%.

5. The apparatus of claim 4, wherein the power supply further comprises an inductor in series with the capacitor, wherein the discharged charge from the capacitor passes through the inductor.

6. The apparatus of claim 1, wherein the amorphous thin film layer comprises titanium nitride.

7. The apparatus of claim 6, wherein the amorphous thin film layer comprises at least about 58% nitrogen and no more than about 42% titanium.

8. The apparatus of claim 1, further comprising a shield power supply which applies a bias voltage to the anode shield with respect to the target.

9. The apparatus of claim 8, further comprising a wafer power supply which applies a bias voltage to the wafer with a magnitude less than a magnitude of the bias voltage applied to the anode shield.

10. The apparatus of claim 1, further comprising a control circuit and a temperature sensor, wherein during the deposition of the amorphous thin film layer the temperature sensor determines a temperature of the substrate and provides an indication of the temperature of the substrate to the control circuit, and wherein the control circuit adjusts at least one operational characteristic of the power supply responsive to the indication and directs a continued deposition of the amorphous thin film layer using an adjusted operational characteristic.

11. The apparatus of claim 1, wherein the amorphous thin film layer is conductive.

12. An apparatus comprising:
a physical vapor deposition (PVD) chamber configured to support a substrate and comprising a cathode target with a layer of sputtering material thereon, an anode shield, and a magnetron assembly adjacent the target;
a high impulse power magnetron sputtering (HiPIMS) power supply coupled to the PVD chamber, the power supply comprising a charging circuit and a charge storage device that comprises a capacitor, and wherein the power supply further comprises a switching circuit that facilitates cyclical storage of charge on the capacitor from the charging circuit and discharge of the stored charge from the capacitor to the magnetron assembly, wherein the power supply applies relatively high energy pulses to the magnetron assembly to sputter, via self ionizing plasma (SIP), relatively low energy ions from the layer of sputtering material to deposit an amorphous conductive thin film layer onto the substrate; and
a control circuit and a temperature sensor, wherein during the deposition of the amorphous conductive thin film layer the temperature sensor determines a temperature of the substrate and provides an indication of the temperature of the substrate to the control circuit, and wherein the control circuit adjusts at least one operational characteristic of the power supply responsive to the indication and directs a continued deposition of the amorphous conductive thin film layer using an adjusted operational characteristic.

13. A method comprising:
providing a physical vapor deposition (PVD) chamber comprising a cathode target with a layer of sputtering material thereon, an anode shield, and a magnetron assembly adjacent the target;
coupling a high impulse power magnetron sputtering (HiPIMS) power supply to the PVD chamber, the power supply comprising a charging circuit and a charge storage device;
supporting a substrate within the chamber; and
depositing an amorphous thin film layer onto the substrate by using the power supply to apply relatively high energy pulses to the magnetron assembly to sputter, via self ionizing plasma (SIP), relatively low energy ions from the layer of sputtering material to the substrate.

14. The method of claim 13, wherein the depositing step comprises bombarding the substrate with titanium and nitrogen ions.

15. The method of claim 13, further comprising a step of monitoring a temperature of the substrate during the depositing step, and adjusting a characteristic of the power supply responsive to a monitored temperature so that continued depositing of the amorphous thin film layer occurs using an adjusted characteristic.

16. The method of claim 13, wherein the depositing step is carried out while a maximum temperature of the substrate is maintained in a range of less than about 150 degrees Celsius without using an active cooling mechanism to cool the substrate.

17. The method of claim 13, wherein the depositing step comprises applying pulses to the magnetron at a duty cycle of from about 0.5% to about 5.0%.

18. The method of claim 13, wherein the amorphous thin film layer is characterized as titanium nitride with substantially no columnar microstructures.

19. The method of claim 13, wherein the amorphous thin film layer is conductive and fills a via through an insulative layer to connect a first conductive layer below the insulative layer to a second conductive layer above the insulative layer.

20. The method of claim 13, wherein an ion flux current density applied to a wafer during the depositing step has a maximum value of less than about 4 amps/cm².
